(19) United States
(12) Patent Application Publication
(10) Pub. No.: US 2024/0003954 A1
(43) Pub. Date: Jan. 4, 2024

(54) LONG-DISTANCE HIGH-VOLTAGE CABLE FAULT DEGREE DETECTION METHOD AND DEVICE

(71) Applicants: ELECTRIC PWR RESEARCH INST. CHINA SOUTH PWR GRID, Guangzhou (CN); SHENZHEN POWER SUPPLY CO., LTD, Guangdong (CN)

(72) Inventors: Shuai HOU, Guangzhou (CN); Mingli FU, Guangzhou (CN); Xiaolin LI, Guangzhou (CN); Wenbo ZHU, Guangzhou (CN); Baojun HUI, Guangzhou (CN); Bin FENG, Guangzhou (CN); Yifan ZHANG, Guangzhou (CN); Guoxing WU, Guangzhou (CN); Hong XIE, Guangzhou (CN); Shu XU, Guangzhou (CN); Xiao CHEN, Guangzhou (CN); Lu CHEN, Guangzhou (CN); Lu ZHAI, Guangzhou (CN)

(73) Assignees: ELECTRIC PWR RESEARCH INST. CHINA SOUTH PWR GRID, Guangzhou (CN); SHENZHEN POWER SUPPLY CO., LTD, Guangdong (CN)

(21) Appl. No.: 18/031,126

(22) PCT Filed: Oct. 21, 2021
(86) PCT No.: PCT/CN2021/125250

§ 371 Date: Apr. 10, 2023

(30) Foreign Application Priority Data
Dec. 30, 2020 (CN) 202011622092.9

(51) Int. Cl. G01R 31/08; G01R 31/11

(52) U.S. Cl. CPC G01R 31/083; G01R 31/11; G01R 31/088

(57) ABSTRACT

A long-distance high-voltage cable fault degree detection method. A cable fault positioning curve is obtained by using a frequency-domain reflection method, and a cable fault positioning compensation curve is determined by means of theoretical calculation in combination with the parameters of a frequency-domain incident signal, cable structure parameters, and characteristic parameters of each layer of materials of the field test; furthermore, a cable fault diagnosis curve is determined on the basis of the cable fault positioning curve and the cable fault positioning compensation curve, the severity of the fault is determined by means of the amplitude of a peak point of the cable fault diagnosis curve, and the accuracy of long-distance high-voltage cable fault degree diagnosis is effectively improved.

### CROSS REFERENCE TO RELATED APPLICATION

The present disclosure is based on and claims priority to Chinese Patent Application with No. 202011622092.9 and filed on Dec. 30, 2020, the content of which is expressly incorporated herein by reference in its entirety.

### TECHNICAL FIELD

The present disclosure relates to the field of high voltage and insulation technologies, particularly to a long-distance high-voltage cable fault degree detection method and device.

### BACKGROUND

With the continuous development of the national economy, the power cables have gradually become the leading product for power transmission in cities. The good and stable operation of dense power cables in cities is directly related to the safety operation of the urban power grids. When the cable fails or has local potential defects, timely and accurate positioning for the fault or defect can greatly reduce the economic loss caused by the long-time power outage repair, and the diagnosis for the severity of the local potential defects, such as the external damage, the insulation deterioration and the insulation moisture of the cable, is convenient for the cable operation and maintenance department to take corresponding measures timely, which is of great significance to improve the operation stability of the electrical power system.

The Frequency Domain Reflectometry (FDR) is regarded as one of the effective methods for the fault location of power cables, which can effectively locate potential defects in cables with small changes in characteristic impedance by a wide-frequency test, such as the external damage, the insulation degradation, etc. The FDR is based on the traveling wave reflection principle. By measuring the frequency domain response characteristics of the cable head-end and using the time-frequency transformation algorithm, the equivalent time-domain response characteristics of the cable head-end are obtained. Furthermore, combined with the speed of signal propagation in the cable, the positioning curve of the FDR test is obtained; and the specific position of the cable fault is determined according to the peak point of the fault positioning curve.

In the traditional FDR method of cable fault location, the severity degree of the cable fault is mainly determined by the amplitude of the peak point in the positioning curve. The larger the amplitude of the peak point, the greater the mismatch degree between the characteristic impedance at the fault position and the characteristic impedance of the cable, the more serious the fault degree of the fault point.

In the process of implementing the present disclosure, the inventors found that the traditional FDR method of cable fault location has the following problems: for long-distance high-voltage cables, due to the affections of the signal frequency and transmission distance, the signal dispersion and attenuation are serious; for the fault points far away from the test port, the amplitude of the peak point at the fault position is greatly reduced, such that it is impossible to accurately determine the severity degree of the cable fault or the local potential defect through the amplitude of the peak point of the FDR positioning curve. Misjudgment of the fault degree of local potential defects can easily lead to the inability to take correct measures during cable operation and maintenance, which greatly affects the safe and stable operation of the power system.

### SUMMARY

In the embodiments of the present disclosure, a long-distance high-voltage cable fault degree detection method and device are provided, which can effectively solve the problem that the prior art cannot accurately judge the severity of cable faults or partial potential defects.

In an embodiment, a long-distance high-voltage cable fault degree detection method is provided, including:
determining parameters of a frequency-domain incident signal according to an on-site situation, and obtaining a cable fault positioning curve by using a Frequency Domain Reflectometry (FDR);
performing a time-frequency transformation on the frequency-domain incident signal according to the parameters of the frequency-domain incident signal, to obtain an equivalent time-domain incident signal;
calculating an attenuation characteristic parameter of a single-frequency sinusoidal incident signal transmitted in a cable according to a structural parameter of the cable and a characteristic parameter of each layer of material;
obtaining a frequency domain response signal attenuated in a transmission distance according to the attenuation characteristic parameter and the parameters of the frequency-domain incident signal;
performing the time-frequency transformation on the frequency domain response signal to obtain an equivalent time-domain response signal attenuated in the transmission distance;
determining a cable fault positioning compensation curve according to the equivalent time-domain incident signal and the equivalent time-domain response signal;
determining a cable fault diagnosis curve based on the cable fault positioning curve and the cable fault positioning compensation curve;
determining a severity degree of a cable fault according to an amplitude of a peak point of the cable fault diagnosis curve.

Optionally, the determining the parameters of the frequency-domain incident signal according to the on-site situation and obtaining the cable fault positioning curve by using the FDR includes:
determining the parameters of the frequency-domain incident signal of the FDR test according to the on-site situation;
using a vector network analyzer to measure a complex reflection coefficient spectrum of a cable head-end based on the parameters of the frequency-domain incident signal;
obtaining the cable fault positioning curve by the time-frequency transformation and windowing processing on the complex reflection coefficient spectrum.

Optionally, the parameters of the frequency-domain incident signal include an amplitude of a sinusoidal linear swept-frequency incident signal, an angular frequency interval of the sinusoidal linear swept-frequency incident signal, a center angular frequency and the number of test points; and
the frequency-domain incident signal is represented as:

$$F [ {ω}_{c} + n Δ ω ] = A ( n = - \frac{N - 1}{2} , - \frac{N + 1}{2} , … , \frac{N - 3}{2} , \frac{N - 1}{2} ) ,$$

where F[ω_{c}+nΔω] is the frequency-domain incident signal, A denotes the amplitude of the sinusoidal linear swept-frequency incident signal, Δω denotes the angular frequency interval of the sinusoidal linear swept-frequency incident signal, N denotes the number of the test points; and ω_{c} denotes the center angular frequency;
and the performing the time-frequency transformation on the frequency-domain incident signal according to the parameters of the frequency-domain incident signal to obtain the equivalent time-domain incident signal includes:
according to the amplitude of the sinusoidal linear swept-frequency incident signal, the center angular frequency and the number of test points, obtaining the equivalent time-domain incident signal by using a following formula:

$$f ( t ) = \frac{A}{N} \cdot \frac{sin ( \frac{N}{2} Δ ω t )}{sin ( \frac{1}{2} Δ ω t )} ,$$

where f(t) denotes the equivalent time-domain incident signal.

Optionally, the calculating the attenuation characteristic parameter of the single-frequency sinusoidal incident signal transmitted in the cable according to the structural parameter of the cable and the characteristic parameter of each layer of material includes:
obtaining the attenuation characteristic parameter during the transmission in the cable by a following formula:

α(ω)=Re(\sqrt{Z_{ω}Y_{ω}})
where α(ω) denotes the attenuation characteristic parameter; Z_{ω} denotes an equivalent distributed impedance per unit length of the cable when the angular frequency is ω; and Y_{ω} denotes an equivalent distributed admittance of the cable per unit length when the angular frequency is ω.

Optionally, the obtaining the frequency domain response signal attenuated in the transmission distance according to the attenuation characteristic parameter and the parameters of the frequency-domain incident signal includes:
obtaining the frequency domain response signal by a following formula:

F′[ω_{c}+nΔω]=A·e^{-α(ω}^{_{c}}^{+nΔω)·l},
where F′[ω_{c}+nΔω] is the frequency domain response signal, l denotes a distance that the sinusoidal linear swept-frequency incident signal is transmitted in the cable, and α(ω_{c}+nΔω) is the attenuation characteristic parameter of the sinusoidal linear swept-frequency incident signal with the angular frequency (ω_{c}+nΔω).

Optionally, the performing the time-frequency transformation on the frequency domain response signal to obtain the equivalent time-domain response signal attenuated in the transmission distance includes:
calculating the equivalent time-domain response signal by a following formula:

$${f}^{′} ( t ) = \frac{1}{{W}_{0}} \cdot {\sum }_{n = - ( N - 1 ) / 2}^{( N - 1 ) / 2} [ A \cdot {e}^{α ( {ω}_{c} + n Δ ω ) \cdot l} \cdot W ( {ω}_{c} + n Δ ω ) \cdot {e}^{j \cdot ( {ω}_{c} + n Δω ) t} ] ,$$

where f′(t) denotes the equivalent time-domain response signal, W(ω_{c}+nΔω) is a window function selected during the windowing processing, and W₀ is a scale factor of the window function.

Optionally, the determining the cable fault positioning compensation curve according to the equivalent time-domain incident signal and the equivalent time-domain response signal includes:
determining the cable fault positioning compensation curve H(l) by a following formula:

$$H ( l ) = \frac{{f}^{′} ( 0 )}{f ( 0 )} = \frac{1}{{W}_{0}} \cdot {\sum }_{n = - ( N - 1 ) / 2}^{( N - 1 ) / 2} [ {e}^{- α ( {ω}_{c} + n Δ ω ) \cdot l} \cdot W ( {ω}_{c} + n Δ ω ) ] ,$$

where H(l) denotes the cable fault positioning compensation curve.

Optionally, the determining the cable fault diagnosis curve based on the cable fault positioning curve and the cable fault positioning compensation curve includes:
determining the cable fault diagnosis curve Q(l) by a following formula:

Q(l)=D(l)−H(2l)
where D(l) denotes the cable fault positioning curve, and Q(l) denotes the cable fault diagnosis curve.

In another embodiment, a long-distance high-voltage cable fault degree detection device is provided, including:
a fault positioning curve determination module, configured to determine parameters of a frequency-domain incident signal according to an on-site situation, and obtain a cable fault positioning curve using a frequency domain reflectometry;
an equivalent time-domain incident signal calculation module, configured to perform a time-frequency transformation on the frequency-domain incident signal according to the determined correlation parameter of the frequency-domain incident signal, to obtain an equivalent time-domain incident signal;
an attenuation characteristic parameter calculation module, configured to calculate an attenuation characteristic parameter of a single-frequency sinusoidal incident signal transmitted in a cable according to a structural parameter of the cable and a characteristic parameter of each layer of material;
a frequency domain response signal calculation module, configured to obtain a frequency domain response signal attenuated in a transmission distance according to the attenuation characteristic parameter and the parameters of the frequency-domain incident signal;
an equivalent time-domain response signal calculation module, configured to perform the time-frequency transformation on the frequency domain response signal to obtain an equivalent time-domain response signal attenuated in the transmission distance;
a fault positioning compensation curve determination module, configured to determine a cable fault positioning compensation curve according to the equivalent time-domain incident signal and the equivalent time-domain response signal;
a fault diagnosis curve determination module, configured to determine a cable fault diagnosis curve based on the cable fault positioning curve and the cable fault positioning compensation curve;
a fault degree determination module, configured to determine a severity degree of the cable fault according to an amplitude of a peak point of the cable fault diagnosis curve.

Compared to the prior art, the present disclosure has the following advantages.

In the fault degree detection method of the long-distance high-voltage cable provided in the embodiment of the present disclosure, the frequency domain reflectometry is used to obtain the cable fault positioning curve, the cable fault positioning compensation curve is determined through the theoretical calculation in combination with the parameters of the frequency domain incident signal tested in the field, the structural parameter of the cable and the material characteristic parameter of each cable layer; the cable fault diagnosis curve is further determined based on the cable fault positioning curve and the cable fault positioning compensation curve; the severity degree of the fault is determined through the amplitudes of the peak points of the cable fault diagnosis curve, thereby effectively improving the accuracy of the diagnosis of the long-distance high-voltage cable fault degree, such that correct and effective measures can be adopted during the operation and maintenance of the cable, and accordingly the safe and stable operation of the electrical power system can be maintained. A long-distance high-voltage cable fault degree detection apparatus is further provided in the embodiment of the present disclosure.

### BRIEF DESCRIPTION OF THE DRAWINGS

FIG. 1 is a flow chart showing a long-distance high-voltage cable fault degree detection method according to an embodiment of the present disclosure.

FIG. 2 is a diagram illustrating a partial external damage defect of a cable used in a fault diagnosis test by using a long-distance high-voltage cable fault degree detection method according to an embodiment of the present disclosure.

FIG. 3 is a cable fault positioning curve diagram obtained by performing a fault diagnosis test with a long-distance high-voltage cable fault degree detection method according to an embodiment of the present disclosure.

FIG. 4 is a cable fault diagnosis curve diagram finally obtained by performing a fault diagnosis test with a long-distance high-voltage cable fault degree detection method according to an embodiment of the present disclosure.

FIG. 5 is a structure block diagram illustrating a long-distance high-voltage cable fault degree detection device according to an embodiment of the present disclosure.

### DETAILED DESCRIPTION

The technical solution in the embodiments of the present disclosure will be clearly and completely described below with reference to the accompanying drawings in the embodiments of the present disclosure. Obviously, the described embodiments are only some embodiments of the present disclosure, but not all the embodiments. Based on the embodiments of the present disclosure, all other embodiments obtained by those of ordinary skill in the art without creative efforts shall fall within the protection scope of the present disclosure.

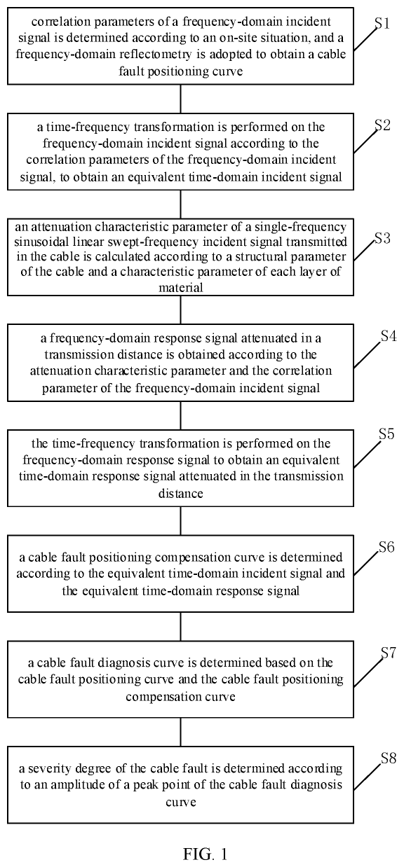

Referring to FIG. 1, which is a flow chart showing a long-distance high-voltage cable fault degree detection method according to an embodiment of the present disclosure.

The present disclosure in an embodiment provides a long-distance high-voltage cable fault degree detection method, which includes the following steps.

Step S1: parameters of a frequency-domain incident signal are determined according to an on-site situation, and a frequency domain reflectometry is adopted to obtain a cable fault positioning curve.

Step S2: a time-frequency transformation is performed on the frequency-domain incident signal according to the parameters of the frequency-domain incident signal, to obtain an equivalent time-domain incident signal.

Step S3: an attenuation characteristic parameter of a single-frequency sinusoidal incident signal transmitted in the cable is calculated according to a structural parameter of the cable and a characteristic parameter of each layer of material.

Step S4: a frequency domain response signal attenuated in a transmission distance is obtained according to the attenuation characteristic parameter and the parameters of the frequency-domain incident signal.

Step S5: the time-frequency transformation is performed on the frequency domain response signal to obtain an equivalent time-domain response signal attenuated in the transmission distance.

Step S6: a cable fault positioning compensation curve is determined according to the equivalent time-domain incident signal and the equivalent time-domain response signal.

Step S7: a cable fault diagnosis curve is determined based on the cable fault positioning curve and the cable fault positioning compensation curve.

Step S8: a severity degree of the cable fault is determined according to an amplitude of a peak point of the cable fault diagnosis curve.

As an optional embodiment, the step S1 “parameters of a frequency-domain incident signal are determined according to an on-site situation, and a frequency domain reflectometry is adopted to obtain a cable fault positioning curve” specifically includes the following steps.

The parameters of the frequency-domain incident signal of the FDR test is determined according to the on-site situation.

Based on the parameters of the frequency-domain incident signal, a vector network analyzer is adopted to measure a complex reflection coefficient spectrum of the cable head-end.

The time-frequency transformation and windowing processing are performed on the complex reflection coefficient spectrum to obtain the cable fault positioning curve.

In a specific embodiment, a window function that can be selected by the windowing processing is any one of a Blackman window, a Chebwin window, or a Kaiser window.

As an optional embodiment, the parameters of the frequency-domain incident signal include an amplitude of the sinusoidal linear swept-frequency incident signal, an angular frequency interval of the sinusoidal linear swept-frequency incident signal, a center angular frequency and the number of the test points;
and, the frequency-domain incident signal is represented as:

$$F [ {ω}_{c} + n Δω ] = A ( n = - \frac{N - 1}{2} , - \frac{N + 1}{2} , … , \frac{N - 3}{2} , \frac{N - 1}{2} ) ;$$

where F′[ω_{c}+nΔω] is the frequency-domain incident signal; A denotes the amplitude of the sinusoidal linear swept-frequency incident signal; Δω denotes the angular frequency interval of the sinusoidal linear swept-frequency incident signal; N denotes the number of the test points; and ω_{c} denotes the center angular frequency.

Further, the step S2 of performing the time-frequency transformation on the frequency-domain incident signal according to the parameters of the frequency-domain incident signal to obtain an equivalent time-domain incident signal specifically includes:
according to the amplitude of the sinusoidal linear swept-frequency incident signal, the center angular frequency and the number of the test points, the equivalent time-domain incident signal is obtained by the following formula:

$$f ( t ) = \frac{A}{N} \cdot \frac{sin ( \frac{N}{2} Δ ω t )}{sin ( \frac{1}{2} Δ ω t )} ;$$

where f(t) denotes the equivalent time-domain incident signal.

As an optional embodiment, the step S3 of calculating the attenuation characteristic parameter of the single-frequency sinusoidal incident signal transmitted in the cable according to the structural parameter of the cable and the characteristic parameter of each layer of material specifically includes:
the attenuation characteristic parameter of the cable transmission is obtained by the following formula:

α(ω)=Re(\sqrt{Z_{ω}Y_{ω}});
where, α(ω) denotes the attenuation characteristic parameter; Z_{ω} denotes an equivalent distributed impedance per unit length of the cable when the angular frequency is ω; and Y_{ω} denotes the equivalent distributed admittance of the cable per unit length when the angular frequency is ω.

In the specific implementation, the equivalent distributed impedance and the equivalent distributed admittance of the cable per unit length can be obtained by calculating based on the structural parameter of the cable and the characteristic parameter of each layer of material.

As an optional embodiment, the step S4 of obtaining the frequency domain response signal attenuated in a certain transmission distance according to the attenuation characteristic parameter and the parameters of the frequency-domain incident signal specifically includes:
the frequency domain response signal is obtained by the following formula:

F′[ω_{c}+nΔω]=A·e^{-α(ω}^{_{c}}^{+nΔω)·l},
where, F′[ω_{c}+nΔω] is the frequency domain response signal; l is a distance that the sinusoidal linear swept-frequency incident signal is transmitted in the cable; and α(ω_{c}+nΔω) is the attenuation characteristic parameter of the sinusoidal linear swept-frequency incident signal with the angular frequency (ω_{c}+nΔω).

As an optional embodiment, the step S5 of performing the time-frequency transformation on the frequency domain response signal to obtain the equivalent time-domain response signal attenuated in the certain transmission distance specifically includes:
the equivalent time-domain response signal is calculated by the following formula:

$${f}^{′} ( t ) = \frac{1}{{W}_{0}} \cdot {\sum }_{n = - ( N - 1 ) / 2}^{( N - 1 ) / 2} [ A \cdot {e}^{α ( {ω}_{c} + n Δ ω ) \cdot l} \cdot W ( {ω}_{c} + n Δ ω ) \cdot {e}^{j \cdot ( {ω}_{c} + n Δ ω ) t} ] ;$$

where, f′(t) is the equivalent time-domain response signal; W(ω_{c}+nΔω) is the window function selected during the windowing processing; W₀ is a scale factor of the window function and can be specifically calculated by the following formula:

$${W}_{0} = {\sum }_{n = - ( N - 1 ) / 2}^{( N - 1 ) / 2} W ( {ω}_{c} + n Δ ω ) .$$

As an optional embodiment, the step S6 of determining the cable fault positioning compensation curve according to the equivalent time-domain incident signal and the equivalent time-domain response signal specifically includes:
the cable fault positioning compensation curve H(l) is determined by the following formula:

$$H ( l ) = \frac{{f}^{′} ( 0 )}{f ( 0 )} = \frac{1}{{W}_{0}} \cdot {\sum }_{n = - ( N - 1 ) / 2}^{( N - 1 ) / 2} [ {e}^{- α ( {ω}_{c} + n Δ ω ) \cdot l} \cdot W ( {ω}_{c} + n Δ ω ) ] ;$$

where, H(l) is the cable fault positioning compensation curve.

As an optional embodiment, the step S7 of determining the cable fault diagnosis curve based on the cable fault positioning curve and the cable fault positioning compensation curve specifically includes:
the cable fault diagnosis curve Q(l) is determined by the following formula:

Q(l)=D(l)−H(2l);
where D(l) is the cable fault positioning curve, and Q(l) is the cable fault diagnosis curve.

In the long-distance high-voltage cable fault degree detection method provided by the embodiment of the present disclosure, the frequency domain reflectometry is adopted to obtain the cable fault positioning curve, and the cable fault positioning compensation curve is determined through the theoretical calculation in combination with the parameters of the frequency-domain incident signal tested on site, the structural parameter of the cable and the characteristic parameter of each layer of material; the cable fault diagnosis curve is further determined based on the cable fault positioning curve and the cable fault positioning compensation curve; and the severity degree of the fault is determined through the amplitude of the peak point of the cable fault diagnosis curve, which effectively improves the accuracy of the diagnosis of the long-distance high-voltage cable fault degree, such that correct and effective measures can be taken during the operation and maintenance of the cable, thereby maintaining the safe and stable operation of the electrical power system.

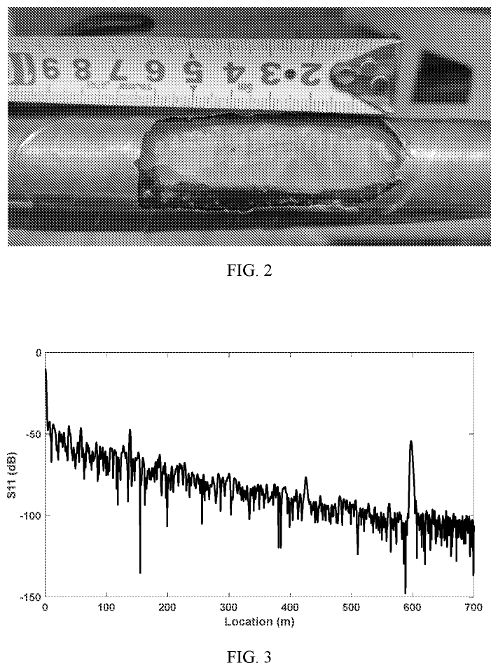

In order to illustrate the process of the present disclosure more clearly, a fault diagnosis test is performed on a 10 kV three-core XLPE power cable with a length of 597 m. A resistance of 300Ω is adopted to connect the wire core and copper shielding layer at 138 m of the sample A-phase to simulate high-resistance grounding, and at the same time, a partial external damage defect is created at a position of 425.34 m to 425.4 m, specifically, reference can be made to the FIG. 2 illustrating a partial external damage defect of a cable. During the test, the remaining two phases that have not failed are grounded, and the terminal of the test cable is open-circuited. The frequency of the test center is 50 MHz, the frequency interval is 62.5 kHz, the number of test points is 1601, and the amplitude of the sinusoidal linear swept-frequency incident signal is 1V. The vector network analyzer is adopted to test at the cable head-end to obtain the complex reflection coefficient spectrum, and the inverse Fourier transform and the Chebwin processing are performed on the complex reflection coefficient spectrum to obtain the cable fault positioning curve D(l). For details, reference can be made to the cable fault positioning curve diagram shown in FIG. 3. As can be seen from FIG. 3, peaks appears at the high-resistance grounding position of the cable of 138.1 m, at the partial external damage defect position of 425.4 m and at the cable terminal of 597.4 m; and the amplitudes of the peak points are −47.5 dB, −76.56, and −54.4 dB respectively. If the severity degree of the fault is diagnosed by the amplitudes of the peak points of the cable fault positioning curve, the larger the amplitude, the more serious the fault; and the fault degree of the open-circuit point of the cable terminal is less than the fault degree of the high-resistance grounding point. However, according to the principle of traveling wave reflection, the amplitude of the reflection coefficient in the case of open circuit or short circuit should be greater than the amplitude of the reflection coefficient in other faults of the cable. Therefore, in this case, the severity degree of the cable fault cannot be accurately determined directly from the amplitudes of the peak points of the cable fault positioning curve.

The equivalent time-domain incident signal is obtained according to the parameter tested by the FDR as:

$$f ( t ) = \frac{A}{N} \frac{sin ( \frac{N}{2} Δ ω t )}{sin ( \frac{1}{2} Δ ω t )} = \frac{1}{1601} \cdot \frac{sin ( 100062500 π t )}{sin ( 62500 π t )} .$$

The attenuation characteristic coefficient of the single-frequency sinusoidal signal transmitted in the cable is calculated according to the structural parameter of the cable and the characteristic parameter of each layer of material as:

α(ω)=2.11ω×10⁻¹¹

Further, the equivalent time-domain response signal attenuated after a transmission distance calculated as:

$${f}^{′} ( t ) = \frac{1}{{W}_{0}} \cdot {\sum }_{n = - 800}^{800} [ {e}^{- 2.11 \times {10}^{- 11} \times ( π \times {10}^{8} + 1.25 \times {10}^{5} \times π \times n ) l} \cdot {W}_{Chebwin} ( π \times {10}^{8} + 1.25 \times {10}^{5} \times π \times n ) \cdot {e}^{j \cdot ( π \times {10}^{8} + 1.25 \times {10}^{5} \times π \times n ) t} ] ,$$

$${W}_{0} = {\sum }_{n = - 800}^{800} {W}_{Chebwin} ( π \times {10}^{8} + 1.25 \times {10}^{5} \times π \times n ) ,$$

Further, the cable fault positioning compensation curve varying with the transmission distance is calculated as:

$$H ( l ) = \frac{1}{{W}_{0}} \cdot {\sum }_{n = - 800}^{800} [ \begin{matrix}{e}^{- 2.11 \times 1 {0}^{- 11} \times ( π \times 1 {0}^{8} + 1.25 \times 10 \times π \times n ) \times t} \cdot \\ {W}_{Chebwin} ( π \times 1 {0}^{8} + 1.25 \times 1 {0}^{5} \times π \times n )\end{matrix} ] .$$

The cable fault diagnosis curve is further obtained as:

$$Y ( l ) = D ( l ) - \frac{1}{{W}_{0}} \cdot {\sum }_{n = - 800}^{800} [ \begin{matrix}{e}^{- 2.11 \times 1 {0}^{- 11} \times ( π \times 1 {0}^{8} + 1.25 \times 10 \times π \times n ) \times 2 l} \cdot \\ {W}_{Chebwin} ( π \times 1 {0}^{8} + 1.25 \times 1 {0}^{5} \times π \times n )\end{matrix} ] .$$

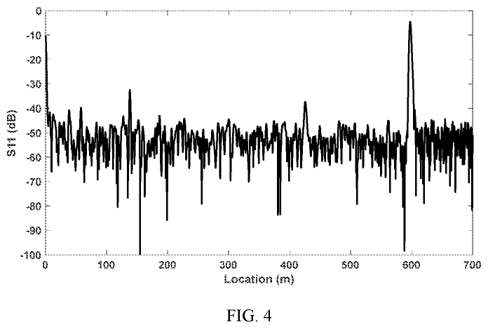

Referring to FIG. 4, which illustrates a finally obtained cable fault diagnosis curve, that is, the cable fault diagnosis curve Y(l) calculated after the attenuation compensation, and this curve has apparent peaks at the high-resistance grounding position of the cable, the partial external damage defect position, and the open-circuit position of the terminal; and the amplitudes of the peaks are −32.46 dB, −37.37 dB and −4.6 dB respectively. According to the traveling wave reflection theory, the amplitude of the reflection coefficient at the open-circuit position of the cable should ideally be 0 dB. But in the actual test, due to the mismatch between characteristic impedances of a test fixture and the cable during the measurement of the complex reflection coefficient spectrum at the cable head-end, there is a certain amplitude weakening at the connection point, so it is reasonable that the amplitude obtained by the test is slightly less than 0 dB, and the amplitude of the peak point at the open-circuit position of the cable terminal is significantly higher than the amplitudes at the high-resistance grounding position of the cable and the partial external damage defect position. Therefore, in the present disclosure, the severity degree of the cable fault can be effectively determined according to the magnitude of the amplitude of the peak point of the cable fault diagnosis curve; and the larger the amplitude of the peak point of the fault diagnosis curve is, the more serious the fault degree of the cable at this position is.

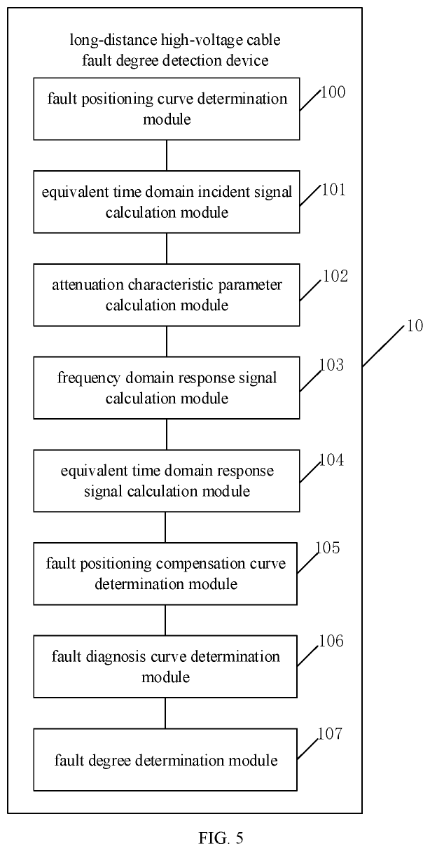

Referring to FIG. 5, it is a structure block diagram of a long-distance high-voltage cable fault degree detection device provided according to an embodiment of the present disclosure.

The long-distance high-voltage cable fault degree detection device 10 provided by the embodiment of the present disclosure includes:
a fault positioning curve determination module 100, configured to determine parameters of a frequency-domain incident signal according to an on-site situation, and obtain a cable fault positioning curve using a frequency domain reflectometry;
an equivalent time-domain incident signal calculation module 101, configured to perform a time-frequency transformation on the frequency-domain incident signal according to the determined correlation parameter of the frequency-domain incident signal, to obtain an equivalent time-domain incident signal;
an attenuation characteristic parameter calculation module 102, configured to calculate an attenuation characteristic parameter of a single-frequency sinusoidal incident signal transmitted in a cable according to a structural parameter of the cable and a characteristic parameter of each layer of material;
a frequency domain response signal calculation module 103, configured to obtain a frequency domain response signal attenuated in a transmission distance according to the attenuation characteristic parameter and the parameters of the frequency-domain incident signal;
an equivalent time-domain response signal calculation module 104, configured to perform the time-frequency transformation on the frequency domain response signal to obtain an equivalent time-domain response signal attenuated in the transmission distance;
a fault positioning compensation curve determination module 105, configured to determine a cable fault positioning compensation curve according to the equivalent time-domain incident signal and the equivalent time-domain response signal;
a fault diagnosis curve determination module 106, configured to determine a cable fault diagnosis curve based on the cable fault positioning curve and the cable fault positioning compensation curve;
a fault degree determination module 107, configured to determine a severity degree of the cable fault according to an amplitude of a peak point of the cable fault diagnosis curve.

It should be noted that the device embodiment described above is only schematic, wherein the units described as separate components may or may not be physically separated, and the components displayed as units may or may not be physical unit, that is, they can be located in one place, or can be distributed over multiple network units. Some or all of the modules can be selected according to actual needs to achieve the solution in this embodiment. In addition, in the drawings of the device embodiments provided by the present disclosure, the connection relationship between the modules indicates that there is a communication connection therebetween, which may be specifically implemented as one or more communication buses or signal lines. Those of ordinary skill in the art can understand and implement it without creative effort.

The above are preferred embodiments of the present disclosure. It should be pointed out that those skilled in the art can make several improvements and modifications without departing from the principle of the present disclosure, and these improvements and modifications can also be regarded as the protection scope of the present disclosure.

1. A long-distance high-voltage cable fault degree detection method, comprising:
determining parameters of a frequency-domain incident signal according to an on-site situation, and obtaining a cable fault positioning curve by using a Frequency Domain Reflectometry (FDR);
performing a time-frequency transformation on the frequency-domain incident signal according to the parameters of the frequency-domain incident signal, to obtain an equivalent time-domain incident signal;
calculating an attenuation characteristic parameter of a single-frequency sinusoidal incident signal transmitted in a cable according to a structural parameter of the cable and a characteristic parameter of each layer of material;
obtaining a frequency domain response signal attenuated in a transmission distance according to the attenuation characteristic parameter and the parameters of the frequency-domain incident signal;
performing the time-frequency transformation on the frequency domain response signal to obtain an equivalent time-domain response signal attenuated in the transmission distance;
determining a cable fault positioning compensation curve according to the equivalent time-domain incident signal and the equivalent time-domain response signal;
determining a cable fault diagnosis curve based on the cable fault positioning curve and the cable fault positioning compensation curve;
determining a severity degree of a cable fault according to an amplitude of a peak point of the cable fault diagnosis curve.

2. The long-distance high-voltage cable fault degree detection method according to claim 1, wherein the determining the parameters of the frequency-domain incident signal according to the on-site situation and obtaining the cable fault positioning curve by using the FDR comprises:
determining the parameters of the frequency-domain incident signal of the FDR test according to the on-site situation;
using a vector network analyzer to measure a complex reflection coefficient spectrum of a cable head-end based on the parameters of the frequency-domain incident signal;
performing the time-frequency transformation and windowing processing on the complex reflection coefficient spectrum to obtain the cable fault positioning curve.

3. The long-distance high-voltage cable fault degree detection method according to claim 2, wherein the parameters of the frequency-domain incident signal comprises an amplitude of a sinusoidal linear swept-frequency incident signal, an angular frequency interval of the sinusoidal linear swept-frequency incident signal, a center angular frequency and the number of test points; and
the frequency-domain incident signal is represented as:
$$F [ {ω}_{c} + n Δ ω ] = A ( n = - \frac{N - 1}{2} , - \frac{N + 1}{2} , … , \frac{N - 3}{2} , \frac{N - 1}{2} ) ,$$
wherein F′[ω_{c}+nΔω] is the frequency-domain incident signal, A denotes the amplitude of the sinusoidal linear swept-frequency incident signal, Δω denotes the angular frequency interval of the sinusoidal linear swept-frequency incident signal, N denotes the number of the test points; and ω_{c} denotes the center angular frequency;
and the performing the time-frequency transformation on the frequency-domain incident signal according to the parameters of the frequency-domain incident signal to obtain the equivalent time-domain incident signal comprises:
according to the amplitude of the sinusoidal linear swept-frequency incident signal, the center angular frequency and the number of test points, obtaining the equivalent time-domain incident signal by using a following formula:
$$f ( t ) = \frac{A}{N} \cdot \frac{sin ( \frac{N}{2} Δω t )}{sin ( \frac{1}{2} Δω t )} ,$$
wherein f(t) denotes the equivalent time-domain incident signal.

4. The long-distance high-voltage cable fault degree detection method according to claim 3, wherein the calculating the attenuation characteristic parameter of the single-frequency sinusoidal incident signal transmitted in the cable according to the structural parameter of the cable and the characteristic parameter of each layer of material comprises:
obtaining the attenuation characteristic parameter during the transmission in the cable by a following formula:
α(ω)=Re(\sqrt{Z_{ω}Y_{ω}})
wherein α(ω) denotes the attenuation characteristic parameter; Z_{ω} denotes an equivalent distributed impedance per unit length of the cable when the angular frequency is ω; and Y_{ω} denotes an equivalent distributed admittance of the cable per unit length when the angular frequency is ω.

5. The long-distance high-voltage cable fault degree detection method according to claim 4, wherein the obtaining the frequency domain response signal attenuated in the transmission distance according to the attenuation characteristic parameter and the parameters of the frequency-domain incident signal comprises:
obtaining the frequency domain response signal by a following formula:
F′[ω_{c}+nΔω]=A·e^{-α(ω}^{_{c}}^{+nΔω)·l},
wherein F′[ω_{c}+nΔω] is the frequency domain response signal, l denotes a distance that the sinusoidal linear swept-frequency incident signal is transmitted in the cable, and α(ω_{c}+nΔω) is the attenuation characteristic parameter of the sinusoidal linear swept-frequency incident signal with the angular frequency (ω_{c}+nΔω).

6. The long-distance high-voltage cable fault degree detection method according to claim 5, wherein the performing the time-frequency transformation on the frequency domain response signal to obtain the equivalent time-domain response signal attenuated in the transmission distance comprises:
calculating the equivalent time-domain response signal by a following formula:
$${f}^{′} ( t ) = \frac{1}{{W}_{0}} \cdot {\sum }_{n = - ( N - 1 ) / 2}^{( N - 1 ) / 2} [ A \cdot {e}^{α ( {ω}_{c} + nΔω ) \cdot l} \cdot W ( {ω}_{c} + n Δ ω ) \cdot {e}^{j \cdot ( {ω}_{c} + n Δω ) t} ] ,$$
wherein f′(t) denotes the equivalent time-domain response signal, W(ω_{c}+nΔω) is a window function selected during the windowing processing, and W₀ is a scale factor of the window function.

7. The long-distance high-voltage cable fault degree detection method according to claim 6, wherein the determining the cable fault positioning compensation curve according to the equivalent time-domain incident signal and the equivalent time-domain response signal comprises:
determining the cable fault positioning compensation curve H(l) by a following formula:
$$H ( l ) = \frac{{f}^{′} ( 0 )}{f ( 0 )} = \frac{1}{{W}_{0}} \cdot {\sum }_{n = - ( N - 1 ) / 2}^{( N - 1 ) / 2} [ {e}^{- α ( {ω}_{c} + n Δ ω ) \cdot l} \cdot W ( {ω}_{c} + n Δ ω ) ] ,$$
wherein H(l) denotes the cable fault positioning compensation curve.

8. The long-distance high-voltage cable fault degree detection method according to claim 7, wherein the determining the cable fault diagnosis curve based on the cable fault positioning curve and the cable fault positioning compensation curve comprises:
determining the cable fault diagnosis curve Q(l) by a following formula:
Q(l)=D(l)−H(2l)
wherein D(l) denotes the cable fault positioning curve, and Q(l) denotes the cable fault diagnosis curve.

9. A long-distance high-voltage cable fault degree detection device, comprising:
a fault positioning curve determination module, configured to determine parameters of a frequency-domain incident signal according to an on-site situation, and obtain a cable fault positioning curve using a frequency domain reflectometry;
an equivalent time-domain incident signal calculation module, configured to perform a time-frequency transformation on the frequency-domain incident signal according to the determined correlation parameter of the frequency-domain incident signal, to obtain an equivalent time-domain incident signal;
an attenuation characteristic parameter calculation module, configured to calculate an attenuation characteristic parameter of a single-frequency sinusoidal linear swept-frequency incident signal transmitted in a cable according to a structural parameter of the cable and a characteristic parameter of each layer of material;
a frequency domain response signal calculation module, configured to obtain a frequency domain response signal attenuated in a transmission distance according to the attenuation characteristic parameter and the parameters of the frequency-domain incident signal;
an equivalent time-domain response signal calculation module, configured to perform the time-frequency transformation on the frequency domain response signal to obtain an equivalent time-domain response signal attenuated in the transmission distance;
a fault positioning compensation curve determination module, configured to determine a cable fault positioning compensation curve according to the equivalent time-domain incident signal and the equivalent time-domain response signal;
a fault diagnosis curve determination module, configured to determine a cable fault diagnosis curve based on the cable fault positioning curve and the cable fault positioning compensation curve;
a fault degree determination module, configured to determine a severity degree of the cable fault according to an amplitude of a peak point of the cable fault diagnosis curve.
